(19) United States
(12) Patent Application Publication
(10) Pub. No.: US 2026/0114010 A1
(43) Pub. Date: Apr. 23, 2026

(54) NITRIDE SEMICONDUCTOR TRANSISTOR

(71) Applicant: SUMITOMO ELECTRIC INDUSTRIES, LTD., Osaka (JP)

(72) Inventors: Makoto YAGI, Osaka (JP); Yuki IMAZEKI, Osaka (JP)

(21) Appl. No.: 19/353,899

(22) Filed: Oct. 9, 2025

(30) Foreign Application Priority Data
Oct. 18, 2024 (JP) 2024-182945

(51) Int. Cl. H10D 64/00; H10D 30/01; H10D 30/47; H10D 62/824; H10D 62/85

(52) U.S. Cl. CPC H10D 64/111; H10D 30/475; H10D 62/824; H10D 30/015; H10D 62/8503

(57) ABSTRACT

A nitride semiconductor transistor includes a nitride semiconductor layer including a channel layer and a barrier layer that are stacked over each other, the nitride semiconductor layer having a first polarization in a first direction; a source electrode, a drain electrode, and a gate electrode that contact the nitride semiconductor layer; a ferroelectric layer located between the gate electrode and the drain electrode in a plan view and having a second polarization in a second direction opposite to the first direction; and a field plate electrically connected to the source electrode and located above the nitride semiconductor layer. The ferroelectric layer is located between the nitride semiconductor layer and the field plate.

### CROSS-REFERENCE TO RELATED APPLICATIONS

This application is based on and claims priority to Japanese Patent Application No. 2024-182945, filed on Oct. 18, 2024, the entire contents of which are incorporated herein by reference.

### TECHNICAL FIELD

The present disclosure relates to a nitride semiconductor transistor.

### BACKGROUND

High electron mobility transistors (HEMTs) having a field plate connected to a source electrode have been proposed. See, for example, U.S. Patent Application Publication No. 2022/0302291.

### SUMMARY

A nitride semiconductor transistor of the present disclosure includes: a nitride semiconductor layer including a channel layer and a barrier layer that are stacked over each other, the nitride semiconductor layer having a first polarization in a first direction; a source electrode, a drain electrode, and a gate electrode that contact the nitride semiconductor layer; a ferroelectric layer located between the gate electrode and the drain electrode in a plan view and having a second polarization in a second direction opposite to the first direction; and a field plate electrically connected to the source electrode and located above the nitride semiconductor layer. The ferroelectric layer is located between the nitride semiconductor layer and the field plate.

### BRIEF DESCRIPTION OF THE DRAWINGS

FIG. 1 is a cross-sectional diagram illustrating a nitride semiconductor transistor according to a first embodiment of the present disclosure.

FIG. 2 is a graph illustrating an example of a band structure of the nitride semiconductor transistor according to the first embodiment.

FIG. 3 is a graph illustrating characteristics of a nitride semiconductor transistor (part 1).

FIG. 4 is a graph illustrating characteristics of a nitride semiconductor transistor (part 2).

FIG. 5 is a cross-sectional diagram illustrating a production method of the nitride semiconductor transistor according to the first embodiment (part 1).

FIG. 6 is a cross-sectional diagram illustrating the production method of the nitride semiconductor transistor according to the first embodiment (part 2).

FIG. 7 is a cross-sectional diagram illustrating the production method of the nitride semiconductor transistor according to the first embodiment (part 3).

FIG. 8 is a cross-sectional diagram illustrating the production method of the nitride semiconductor transistor according to the first embodiment (part 4).

FIG. 9 is a cross-sectional diagram illustrating the production method of the nitride semiconductor transistor according to the first embodiment (part 5).

FIG. 10 is a cross-sectional diagram illustrating a nitride semiconductor transistor according to a second embodiment of the present disclosure.

FIG. 11 is a cross-sectional diagram illustrating a nitride semiconductor transistor according to a third embodiment of the present disclosure.

### DETAILED DESCRIPTION

In recent years, there has been a growing need for further improvement in distortion characteristics. As used herein, the distortion characteristics are distortion characteristics of an output amplitude relative to an input amplitude when using a transistor as an amplifier, i.e., amplitude modulation-amplitude modulation characteristics, known as AM-AM characteristics.

The present disclosure provides a nitride semiconductor transistor having enhanced distortion characteristics.

### [Description of Embodiments of the Present Disclosure]

First, embodiments of the present disclosure will be described.

[1] A nitride semiconductor transistor according to an aspect of the present disclosure includes: a nitride semiconductor layer including a channel layer and a barrier layer that are stacked over each other, the nitride semiconductor layer having a first polarization in a first direction; a source electrode, a drain electrode, and a gate electrode that contact the nitride semiconductor layer; a ferroelectric layer located between the gate electrode and the drain electrode in a plan view and having a second polarization in a second direction opposite to the first direction; and a field plate electrically connected to the source electrode and located above the nitride semiconductor layer, in which the ferroelectric layer is located between the nitride semiconductor layer and the field plate.

The ferroelectric layer is located between the nitride semiconductor layer and the field plate, the nitride semiconductor layer has a first polarization, and the ferroelectric layer has a second polarization directed opposite to the first polarization. Therefore, a depletion layer tends to expand in a region located between the gate electrode and the drain electrode in the plan view, and thus even if a source-drain current increases, a capacitance between the gate electrode and the drain electrode and a capacitance between the drain electrode and the source electrode do not tend to increase. Therefore, it is possible to enhance the distortion characteristics (AM-AM characteristics) of the output amplitude relative to the input amplitude.

[2] In [1], the nitride semiconductor transistor may further include: a first insulating film located over the nitride semiconductor layer and including a first opening that reaches the nitride semiconductor layer; and a second insulating film located over the first insulating film and including a second opening that reaches the first insulating film, in which the gate electrode may contact the nitride semiconductor layer through the first opening, and the ferroelectric layer may contact the first insulating film through the second opening. In this case, the gate electrode and the ferroelectric layer can be formed stably.

[3] In [1] or [2], the ferroelectric layer may be a nitride layer containing aluminum, and at least one selected from the group consisting of scandium, boron, and yttrium. In this case, the ferroelectric layer tends to have a large remnant polarization.

[4] In [3], the ferroelectric layer may be an aluminum scandium nitride layer, and in the aluminum scandium nitride layer, a ratio of a number of scandium atoms to a total number of aluminum atoms and the scandium atoms may be 40% or less. In this case, the aluminum scandium nitride layer tends to have a wurtzite-type crystal structure.

[5] In [3], the ferroelectric layer may be an aluminum yttrium nitride layer, and in the aluminum yttrium nitride layer, a ratio of a number of yttrium atoms to a total number of aluminum atoms and the yttrium atoms may be 80% or less. In this case, the aluminum yttrium nitride layer tends to have a wurtzite-type crystal structure.

[6] In [1] or [2], the ferroelectric layer may be a hafnium oxide layer containing at least one selected from the group consisting of zirconium, yttrium, lanthanum, and silicon. In this case, the ferroelectric layer tends to have a large remnant polarization.

[7] In [1] or [2], the ferroelectric layer may be an oxide layer containing at least one selected from the group consisting of barium, bismuth, lead, and titanium, and having a perovskite-type crystal structure. In this case, the ferroelectric layer tends to have a large remnant polarization.

[8] In any one of [1] to [7], the nitride semiconductor layer may include a first surface that the gate electrode contacts, and the first surface may have metal polarity. In this case, the nitride semiconductor layer can be formed stably.

### [Details of Embodiments of Present Disclosure]

Embodiments of the present disclosure will be described below in detail, but the present disclosure is not limited thereto. In the present specification and drawings, components having substantially the same functional configuration are denoted by the same symbols, and duplicate description thereof may be omitted. In the present disclosure, the “plan view” means viewing an object from above. In the present disclosure, a direction in which the nitride semiconductor layer is located as viewed from the substrate is defined as being above.

### (First Embodiment)

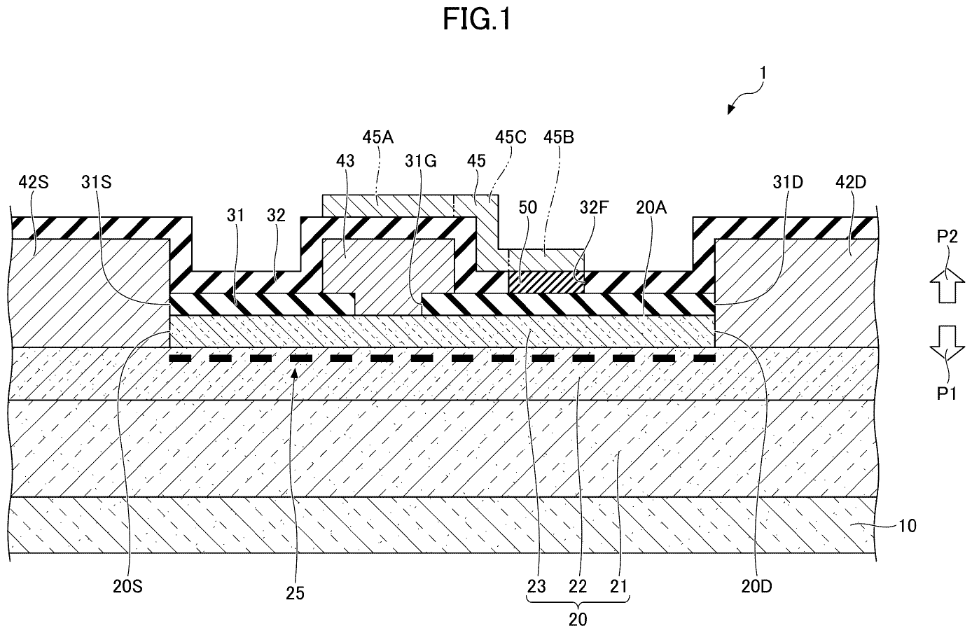

A first embodiment of the present disclosure relates to a nitride semiconductor transistor. The nitride semiconductor transistor is, for example, a gallium nitride-based high electron mobility transistor (HEMT). FIG. 1 is a cross-sectional diagram illustrating the nitride semiconductor transistor according to the first embodiment.

As illustrated in FIG. 1, a nitride semiconductor transistor 1 according to the first embodiment includes a substrate 10, a nitride semiconductor layer 20, a ferroelectric layer 50, an insulating film 31, an insulating film 32, a gate electrode 43, a source electrode 42S, a drain electrode 42D, and a field plate 45.

The substrate 10 is, for example, a semi-insulating silicon carbide (SiC) substrate. When the substrate 10 is an SiC substrate, the top surface of the substrate 10 is a silicon (Si) polar surface.

The nitride semiconductor layer 20 includes a buffer layer 21, a channel layer 22, and a barrier layer 23. The nitride semiconductor layer 20 may include a nucleation layer between the substrate 10 and the buffer layer 21. The nitride semiconductor layer 20 includes a top surface 20A.

The top surface 20A has metal polarity. The top surface 20A is an example of the first surface.

The buffer layer 21 is located over the substrate 10. The buffer layer 21 is, for example, a gallium nitride (GaN) layer. The thickness of the buffer layer 21 is, for example, 100 nanometers (nm) or more and 2,000 nanometers (nm) or less.

The channel layer 22 is located over the buffer layer 21. The channel layer 22 includes a top surface having metal polarity. The channel layer 22 is, for example, a gallium nitride (GaN) layer. The thickness of the channel layer 22 is, for example, 5 nm or more and 40 nm or less. The conductivity type of the channel layer 22 is, for example, an n-type or undoped type (i-type). The buffer layer 21 and the channel layer 22 do not necessarily need to be distinguished from each other.

The barrier layer 23 is located over the channel layer 22. The channel layer 22 and the barrier layer 23 are stacked over each other. The barrier layer 23 includes the top surface having metal polarity. The barrier layer 23 is, for example, an aluminum gallium nitride (AlGaN) layer. The electron affinity of the barrier layer 23 is lower than the electron affinity of the channel layer 22. The band gap of the barrier layer 23 is greater than the band gap of the channel layer 22.

The thickness of the barrier layer 23 is, for example, 5 nm or more and 40 nm or less. The composition of the barrier layer 23 is, for example, Al_{Y}Ga_{1-Y}N (0.15≤Y≤0.55). That is, in the AlGaN layer, a ratio of the number of Al atoms to the total number of the Al atoms and Ga atoms (Al compositional ratio) is 15% or more and 55% or less. The conductivity type of the barrier layer 23 is, for example, an n-type or undoped type (i-type).

The nitride semiconductor layer 20 has a polarization P1 directed from the top surface 20A toward the bottom surface. The polarization P1 is an example of the first polarization.

A recess 20S for a source and a recess 20D for a drain are formed in the nitride semiconductor layer 20. The recess 20S and the recess 20D penetrate through the barrier layer 23. The recess 20S and the recess 20D may further penetrate through the channel layer 22. The bottom of the recess 20S and the bottom of the recess 20D may be located in the channel layer 22 or may be located in the buffer layer 21.

The insulating film 31 is located over the barrier layer 23. The insulating film 31 is, for example, a silicon nitride (SiN) film. The thickness of the insulating film 31 is, for example, 5 nm or more and 100 nm or less. An opening 31S for a source, an opening 31D for a drain, and an opening 31G for a gate are formed in the insulating film 31. The opening 31S is continuous with the recess 20S, and the opening 31D is continuous with the recess 20D. In the plan view, the opening 31G is located between the opening 31S and the opening 31D. The opening 31G reaches the barrier layer 23. The insulating film 31 is an example of the first insulating film, and the opening 31G is an example of the first opening.

The source electrode 42S is located over the channel layer 22 or the buffer layer 21 in the recess 20S. The drain electrode 42D is located over the channel layer 22 or the buffer layer 21 in the recess 20D. The source electrode 42S and the drain electrode 42D contact the nitride semiconductor layer 20. The source electrode 42S and the drain electrode 42D are in ohmic contact with the nitride semiconductor layer 20.

In the plan view, the gate electrode 43 is located between the source electrode 42S and the drain electrode 42D. The gate electrode 43 is located over the insulating film 31, and contacts the barrier layer 23 through the opening 31G.

A cap layer may be provided over the barrier layer 23. When the cap layer is provided over the barrier layer 23, the insulating film 31 is located over the cap layer, and the gate electrode 43 contacts the cap layer through the opening 31G.

The cap layer is, for example, a gallium nitride (GaN) layer.

The insulating film 32 is located over the insulating film 31, the source electrode 42S, the drain electrode 42D, and the gate electrode 43. The insulating film 32 covers the insulating film 31, the source electrode 42S, the drain electrode 42D, and the gate electrode 43. The insulating film 32 is, for example, a silicon nitride (SiN) film. The thickness of the insulating film 32 is, for example, 5 nm or more and 100 nm or less. An opening 32F reaching the insulating film 31 is formed in the insulating film 32. The opening 32F is located between the gate electrode 43 and the drain electrode 42D in the plan view. The insulating film 32 may include an opening reaching the source electrode 42S, an opening reaching the drain electrode 42D, and an opening reaching the gate electrode 43.

The ferroelectric layer 50 contacts the insulating film 31 through the opening 32F. For example, the ferroelectric layer 50 is located inside the opening 32F. The ferroelectric layer 50 has a polarization P2 directed from the bottom surface to the top surface. That is, the polarization P2 is directed opposite to the polarization P1. The ferroelectric layer 50 is located between the gate electrode 43 and the drain electrode 42D in the plan view. The polarization P2 is an example of the second polarization.

The field plate 45 is located above the nitride semiconductor layer 20 and over the insulating film 32 and the ferroelectric layer 50.

The field plate 45 includes a first portion 45A, a second portion 45B, and a third portion 45C. The first portion 45A is stacked over the gate electrode 43 in the plan view. The second portion 45B is stacked over the ferroelectric layer 50 in the plan view. The third portion 45C is located between the first portion 45A and the second portion 45B in the plan view, and connects the first portion 45A and the second portion 45B. The field plate 45 is electrically connected to the source electrode 42S. The ferroelectric layer 50 is located between the nitride semiconductor layer 20 and the field plate 45.

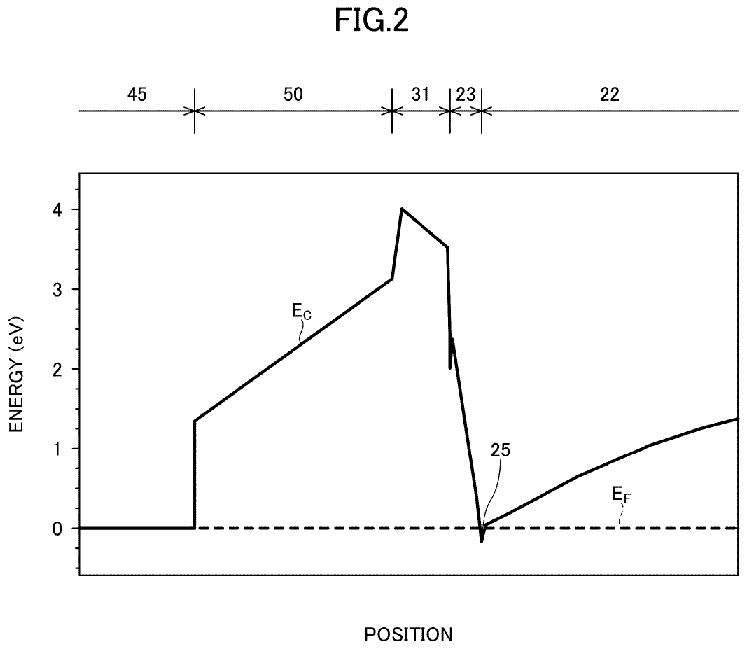

Here, an example of a band structure of the nitride semiconductor transistor 1 will be described. FIG. 2 is a graph illustrating an example of the band structure of the nitride semiconductor transistor 1 according to the first embodiment. FIG. 2 illustrates a Fermi level EF and a lower end EC of a conduction band. In FIG. 2, the horizontal axis indicates a position of the nitride semiconductor transistor 1 in the direction from the top surface to the bottom surface in a portion including the ferroelectric layer 50, and the vertical axis indicates energy based on the Fermi level EF.

In the nitride semiconductor transistor 1, a two-dimensional electron gas (2DEG) 25 is generated near the top surface of the channel layer 22, as illustrated in FIGS. 1 and 2. However, because the ferroelectric layer 50 is located between the nitride semiconductor layer 20 and the field plate 45, the nitride semiconductor layer 20 has the polarization P1, and the ferroelectric layer 50 has the polarization P2 directed opposite to the polarization P1, the two-dimensional electron gas 25 near the ferroelectric layer 50 is reduced through partial depolarization. Therefore, the depletion layer tends to expand in a region located between the gate electrode 43 and the drain electrode 42D in the plan view, and thus even if a source-drain current Ids increases, a capacitance Cgd between the gate electrode 43 and the drain electrode 42D and a capacitance Cds between the drain electrode 42D and the source electrode 42S do not tend to increase. It is therefore possible to enhance the distortion characteristics (AM-AM characteristics) of the output amplitude relative to the input amplitude.

That is, it is possible to reduce nonlinearity, i.e., deviation from a proportional relationship after output power is saturated in response to a large quantity of input power.

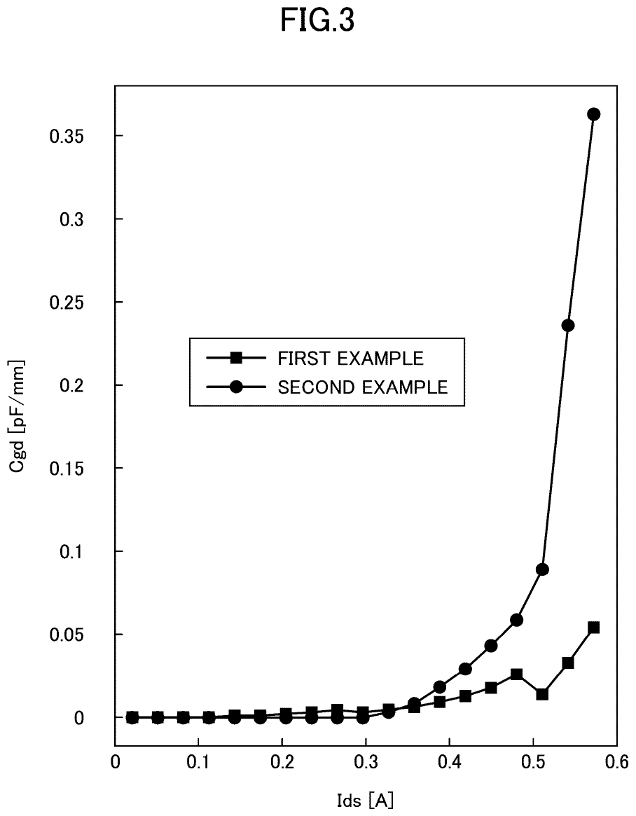

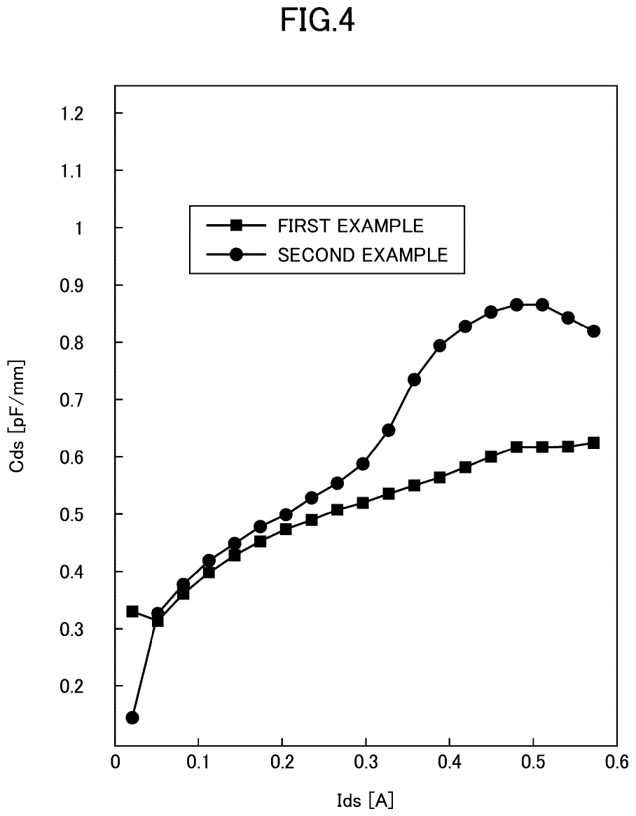

FIGS. 3 and 4 are graphs illustrating characteristics of two different nitride semiconductor transistors. A first example represents the first embodiment. A second example is an example identical to the first embodiment except that the opening 32F is not formed in the insulating film 32, the ferroelectric layer 50 is absent, and the insulating film 32 is located between the nitride semiconductor layer 20 and the field plate 45. In FIG. 3, the horizontal axis indicates a current Ids, and the vertical axis indicates a capacitance Cgd. In FIG. 4, the horizontal axis indicates a current Ids, and the vertical axis indicates a capacitance Cds.

As illustrated in FIGS. 3 and 4, when the current Ids increases, the capacitance Cgd and the capacitance Cds do not tend to increase in the first example compared to the second example. Therefore, according to the first example, it is possible to enhance distortion characteristics compared to the second example.

The ferroelectric layer 50 is, for example, a nitride layer having a wurtzite-type crystal structure, a hafnium oxide layer, or an oxide layer having a perovskite-type crystal structure.

The nitride layer is, for example, a nitride layer containing aluminum (Al), and at least one selected from the group consisting of scandium (Sc), boron (B), and yttrium (Y). In this case, the ferroelectric layer 50 tends to have a large remnant polarization. When the ferroelectric layer 50 is an aluminum scandium nitride layer, and in the aluminum scandium nitride layer, a ratio of the number of Sc atoms to the total number of Al and the Sc atoms (Sc compositional ratio) is 40% or less, the aluminum scandium nitride layer tends to have a wurtzite-type crystal structure. When the ferroelectric layer 50 is an aluminum yttrium nitride layer, and in the aluminum yttrium nitride layer, a ratio of the number of Y atoms to the total number of Al atoms and the Y atoms (Y compositional ratio) is 80% or less, the aluminum yttrium nitride layer tends to have a wurtzite-type crystal structure. The ferroelectric layer 50 may further contain gallium (Ga), indium (In), or both. When the ferroelectric layer 50 contains gallium, it is possible to lower a coercive electric field of the ferroelectric layer 50.

The Sc compositional ratio and the Y compositional ratio can be measured, for example, through transmission electron microscope-energy dispersive X-ray spectroscopy (TEM-EDX), secondary ion mass spectrometry (SIMS), or X-ray photoelectron spectroscopy.

The hafnium oxide layer is, for example, a hafnium oxide layer containing at least one selected from the group consisting of zirconium (Zr), yttrium (Y), lanthanum (La), and silicon (Si). In this case, the ferroelectric layer 50 tends to have a large remnant polarization.

The oxide layer having a perovskite-type crystal structure is, for example, an oxide layer containing at least one selected from the group consisting of barium (Ba), bismuth (Bi), lead (Pb), and titanium (Ti). In this case, the ferroelectric layer 50 tends to have a large remnant polarization.

The ferroelectric layer 50 may further contain at least one selected from the group consisting of indium (In), selenium (Se), molybdenum (Mo), and tellurium (Te).

The direction of the polarization of the ferroelectric layer 50 can be identified by measuring an electric field inside the ferroelectric layer 50 using a transmission electron microscope (TEM) or the like.

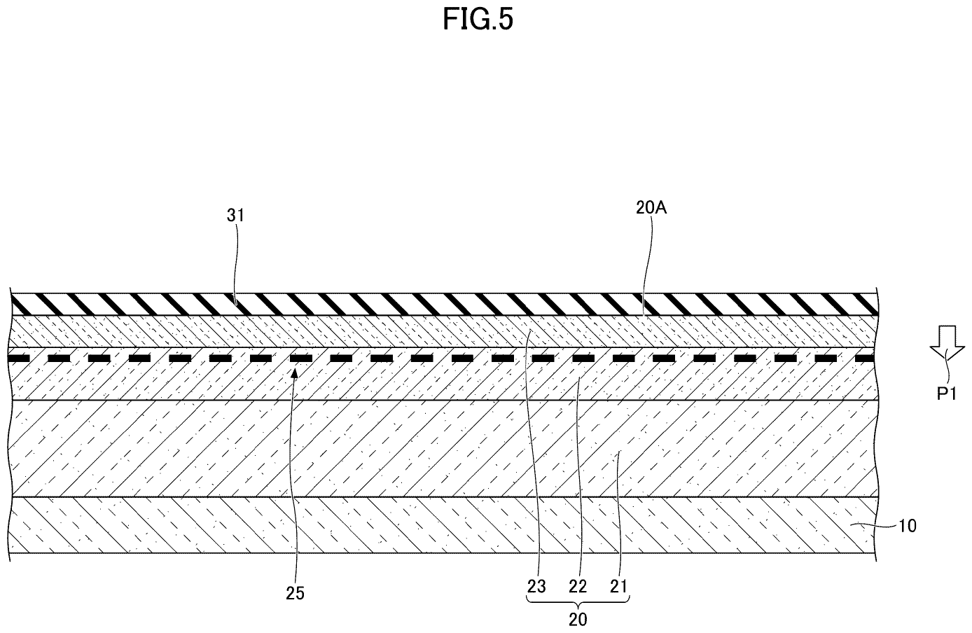

Next, a production method of the nitride semiconductor transistor 1 according to the first embodiment will be described. FIGS. 5 to 9 are cross-sectional diagrams illustrating the production method of the nitride semiconductor transistor 1 according to the first embodiment.

First, as illustrated in FIG. 5, the buffer layer 21, the channel layer 22, and the barrier layer 23 are sequentially formed over the substrate 10, for example, through metal organic chemical vapor deposition (MOCVD). At this time, the top surface of the buffer layer 21, the top surface of the channel layer 22, and the top surface of the barrier layer 23 have metal polarity, and the two-dimensional electron gas 25 is generated near the top surface of the channel layer 22. The nitride semiconductor layer 20 has the polarization P1 directed from the top surface 20A toward the bottom surface. Next, the insulating film 31 is formed over the barrier layer 23.

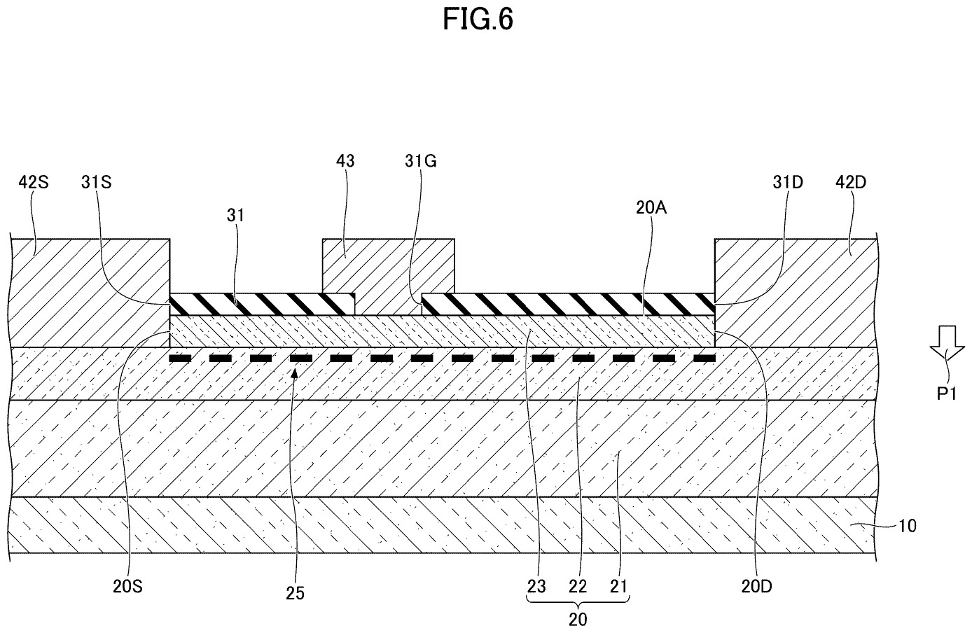

Next, as illustrated in FIG. 6, the opening 31S for the source and the opening 31D for the drain are formed in the insulating film 31, and the recess 20S for the source and the recess 20D for the drain are formed in the nitride semiconductor layer 20. The opening 31S, the opening 31D, the recess 20S, and the recess 20D can be formed, for example, through reactive ion etching (RIE) using a mask (not shown).

Next, the source electrode 42S is formed over the channel layer 22 or the buffer layer 21 in the recess 20S, and the drain electrode 42D is formed over the channel layer 22 or the buffer layer 21 in the recess 20D. In the formation of the source electrode 42S and the drain electrode 42D, first, a metal layer (not shown) forming the source electrode 42S and the drain electrode 42D is formed. In the formation of the metal layer, for example, a film is formed using a mask for growth (not shown) including an opening formed in a region where the metal layer is to be formed, and then the mask for growth is removed along with the metal layer (not shown) formed on the mask for growth. That is, lift-off is performed.

Next, the opening 31G for the gate is formed in the insulating film 31. The opening 31G can be formed, for example, through RIE using a mask (not shown). Next, the gate electrode 43 to contact the barrier layer 23 through the opening 31G is formed over the insulating film 31. In the formation of the gate electrode 43, for example, a metal layer is formed using a mask for growth (not shown) including an opening formed in a region where the gate electrode 43 is to be formed, and then the mask for growth is removed along with the metal layer (not shown) formed on the mask for growth. That is, lift-off is performed.

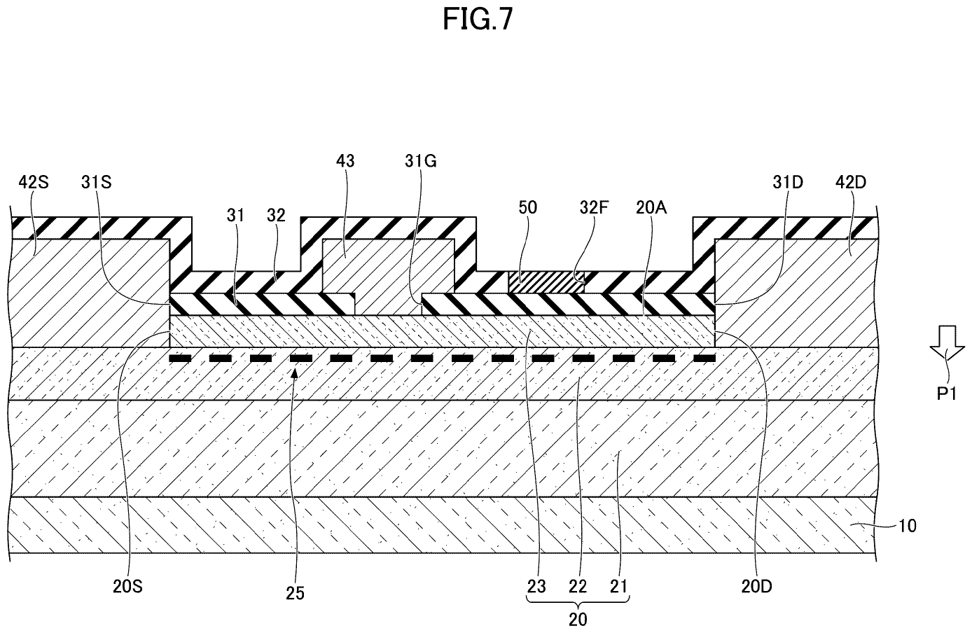

Next, as illustrated in FIG. 7, the insulating film 32 is formed over the insulating film 31, the source electrode 42S, the drain electrode 42D, and the gate electrode 43. Next, the opening 32F is formed in the insulating film 32. The opening 32F can be formed, for example, through RIE using a mask (not shown). Next, the ferroelectric layer 50 to contact the insulating film 31 through the opening 32F is formed. The ferroelectric layer 50 can be formed, for example, through sputtering, chemical vapor deposition (CVD), electron beam epitaxy (MBE), or atomic layer deposition (ALD). At this time, the polarization of the ferroelectric layer 50 may be directed in any direction.

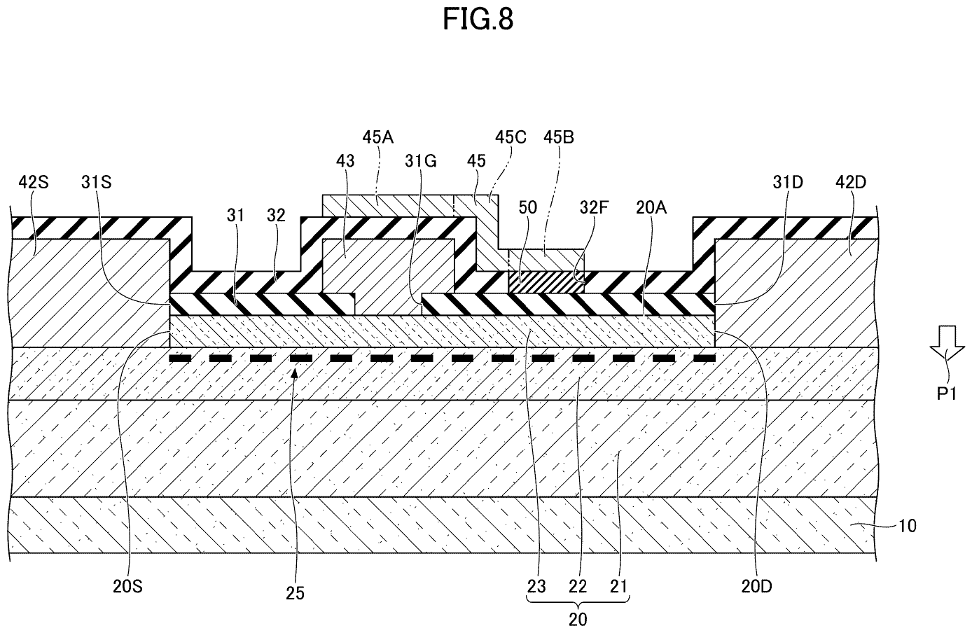

Next, as illustrated in FIG. 8, the field plate 45 having the first portion 45A, the second portion 45B, and the third portion 45C is formed over the insulating film 32 and the ferroelectric layer 50. At this time, the field plate 45 is electrically insulated from the source electrode 42S. In the formation of the field plate 45, first, a metal layer (not shown) forming the field plate 45 is formed. In the formation of the metal layer, for example, a film is formed using a mask for growth (not shown) including an opening formed in a region where the metal layer is to be formed, and then the mask for growth is removed along with the metal layer (not shown) formed on the mask for growth. That is, lift-off is performed.

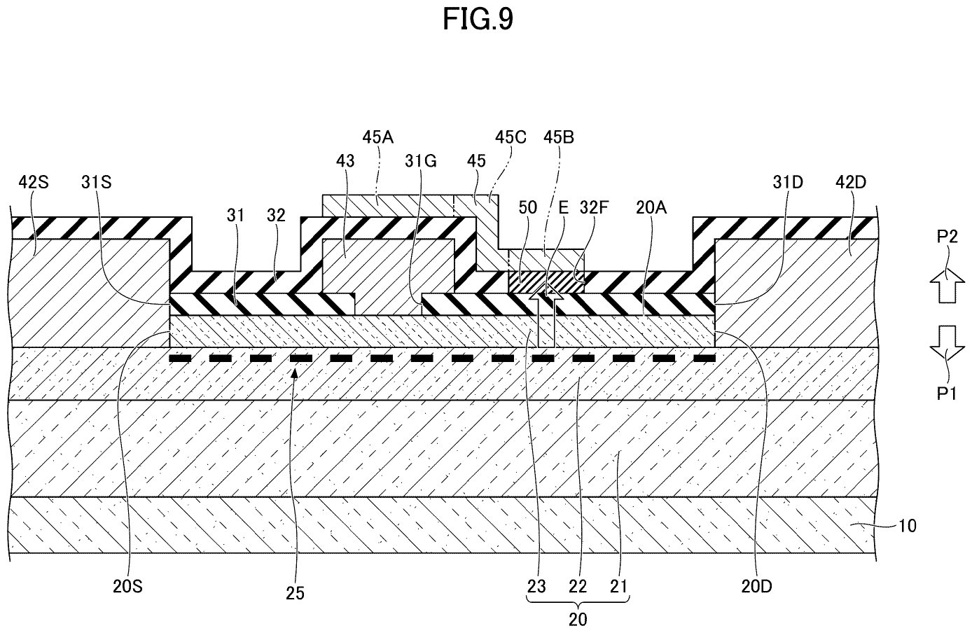

Next, as illustrated in FIG. 9, by applying, to the ferroelectric layer 50, an electric field E equal to or greater than the coercive electric field of the ferroelectric layer 50, the ferroelectric layer 50 is caused to have the polarization P2 directed opposite to the polarization P1. For example, by applying a voltage between the source electrode 42S and the field plate 45, the electric field E can be applied to the ferroelectric layer 50. When controlling the polarization P2, the ferroelectric layer 50 may be heated to a temperature that is about 500 degrees Celsius (° C.) or less.

Next, the field plate 45 and the source electrode 42S are electrically connected. For example, a metal layer continuous with the field plate 45 and the source electrode 42S is formed.

In this manner, the nitride semiconductor transistor 1 can be produced.

The gate electrode 43 contacts the nitride semiconductor layer 20 through the opening 31G, and the ferroelectric layer 50 contacts the insulating film 31 through the opening 32F, thereby easily forming the gate electrode 43 and the ferroelectric layer 50 stably.

Because the top surface 20A of the nitride semiconductor layer 20 has metal polarity, the nitride semiconductor layer 20 can be easily formed stably. The top surface 20A of the nitride semiconductor layer 20 may have nitrogen polarity.

No particular limitation is imposed on the method and timing for controlling the polarization of the ferroelectric layer 50. Also, the insulating film 32 may be formed after the formation of the ferroelectric layer 50.

No particular limitation is imposed on the depth of the opening 32F. The opening 32F does not necessarily need to penetrate through the insulating film 32. Also, the opening 32F may enter the insulating film 31.

### (Second Embodiment)

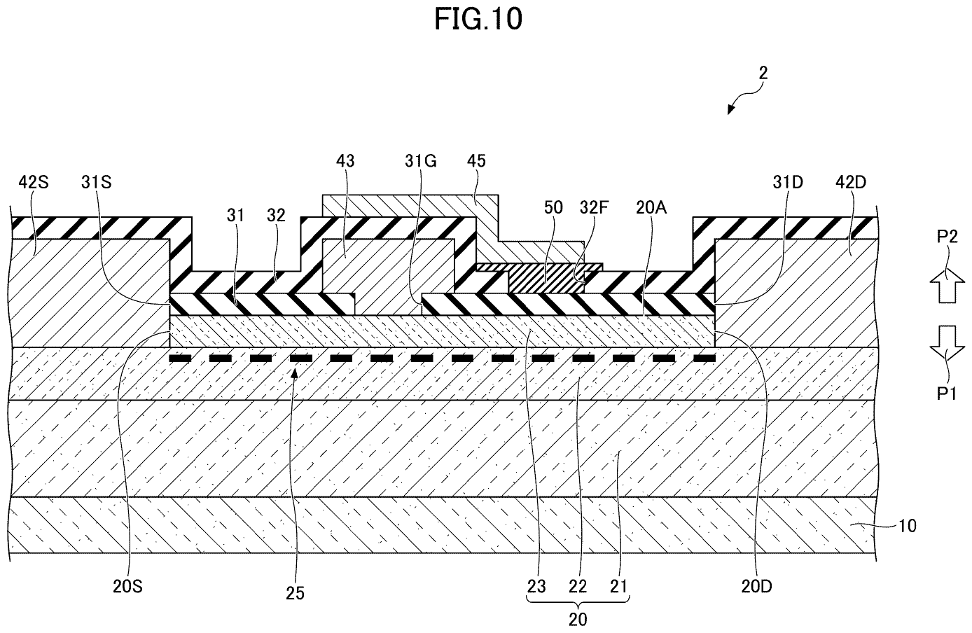

A second embodiment is different from the first embodiment mainly in the configuration of the ferroelectric layer 50. FIG. 10 is a cross-sectional diagram illustrating a nitride semiconductor transistor according to the second embodiment.

As illustrated in FIG. 10, in a nitride semiconductor transistor 2 according to the second embodiment, the ferroelectric layer 50 is located not only inside the opening 32F, but also over the top surface of the insulating film 32.

Other configurations of the nitride semiconductor transistor 2 are the same as those of the nitride semiconductor transistor 1.

The nitride semiconductor transistor 2 can provide the same effects as those provided by the nitride semiconductor transistor 1.

### (Third Embodiment)

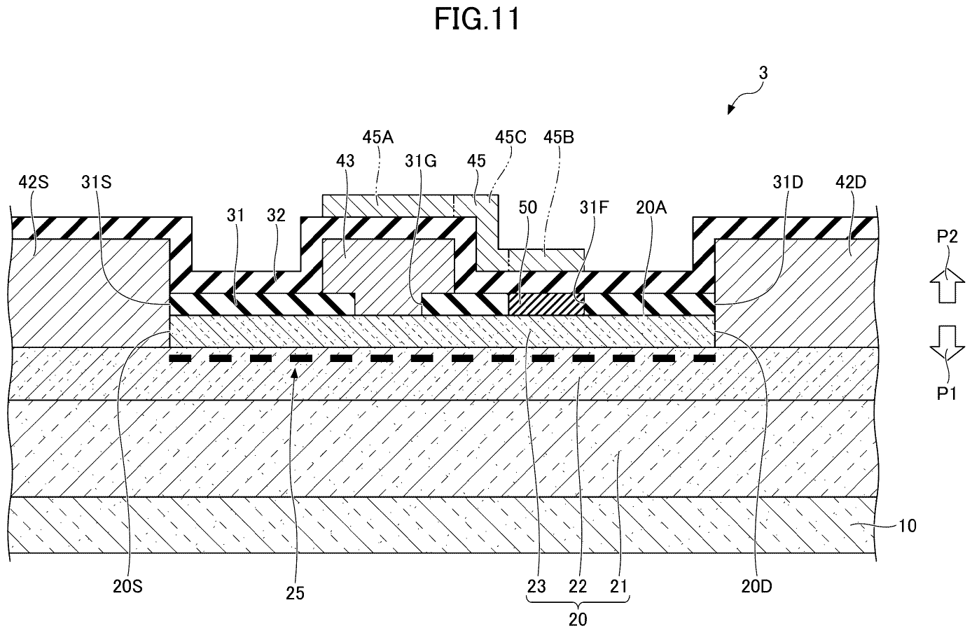

A third embodiment is different from the first embodiment mainly in the configuration of the insulating film. FIG. 11 is a cross-sectional diagram illustrating a nitride semiconductor transistor according to the third embodiment.

As illustrated in FIG. 11, in a nitride semiconductor transistor 3 according to the third embodiment, an opening 31F is formed in the insulating film 31. The opening 31F is located between the gate electrode 43 and the drain electrode 42D in the plan view. The ferroelectric layer 50 contacts the barrier layer 23 through the opening 31F. For example, the ferroelectric layer 50 is located inside the opening 31F. The opening 32F is not formed in the insulating film 32.

Other configurations of the nitride semiconductor transistor 3 are the same as those of the nitride semiconductor transistor 1.

The nitride semiconductor transistor 3 can provide the same effects as those provided by the nitride semiconductor transistor 1.

In the formation of the nitride semiconductor transistor 3, the ferroelectric layer 50 may be formed after the formation of the insulating film 31, or the insulating film 31 may be formed after the formation of the ferroelectric layer 50. Also, the opening 31F does not necessarily need to penetrate through the insulating film 31, or the ferroelectric layer 50 does not necessarily need to contact the barrier layer 23.

Although the embodiments have been described above in detail, the present disclosure is not limited to the specific embodiments. Various modifications and alterations are possible within the scope of claims recited.

According to the present disclosure, it is possible to enhance distortion characteristics.

What is claimed is:

1. A nitride semiconductor transistor, comprising:
a nitride semiconductor layer including a channel layer and a barrier layer that are stacked over each other, the nitride semiconductor layer having a first polarization in a first direction;
a source electrode, a drain electrode, and a gate electrode that contact the nitride semiconductor layer;
a ferroelectric layer located between the gate electrode and the drain electrode in a plan view and having a second polarization in a second direction opposite to the first direction; and
a field plate electrically connected to the source electrode and located above the nitride semiconductor layer, wherein
the ferroelectric layer is located between the nitride semiconductor layer and the field plate.

2. The nitride semiconductor transistor according to claim 1, further comprising:
a first insulating film located over the nitride semiconductor layer and including a first opening that reaches the nitride semiconductor layer; and
a second insulating film located over the first insulating film and including a second opening that reaches the first insulating film, wherein
the gate electrode contacts the nitride semiconductor layer through the first opening, and
the ferroelectric layer contacts the first insulating film through the second opening.

3. The nitride semiconductor transistor according to claim 1, wherein
the ferroelectric layer is a nitride layer containing aluminum, and at least one selected from the group consisting of scandium, boron, and yttrium.

4. The nitride semiconductor transistor according to claim 3, wherein
the ferroelectric layer is an aluminum scandium nitride layer, and
in the aluminum scandium nitride layer, a ratio of a number of scandium atoms to a total number of aluminum atoms and the scandium atoms is 40% or less.

5. The nitride semiconductor transistor according to claim 3, wherein
the ferroelectric layer is an aluminum yttrium nitride layer, and
in the aluminum yttrium nitride layer, a ratio of a number of yttrium atoms to a total number of aluminum atoms and the yttrium atoms is 80% or less.

6. The nitride semiconductor transistor according to claim 1, wherein
the ferroelectric layer is a hafnium oxide layer containing at least one selected from the group consisting of zirconium, yttrium, lanthanum, and silicon.

7. The nitride semiconductor transistor according to claim 1, wherein
the ferroelectric layer is an oxide layer containing at least one selected from the group consisting of barium, bismuth, lead, and titanium, and having a perovskite-type crystal structure.

8. The nitride semiconductor transistor according to claim 1, wherein
the nitride semiconductor layer includes a first surface that the gate electrode contacts, and
the first surface has metal polarity.
